(19) United States
(12) Patent Application Publication
(10) Pub. No.: US 2002/0106829 A1
(43) Pub. Date: Aug. 8, 2002

(54) Conditioning wheel for conditioning a semiconductor wafer polishing pad and method of manufacture thereof

(76) Inventors: Arun K. Nanda, Orlando, FL (US); Jose Omar Rodriguez, Orlando, FL (US); Laurence D. Schultz, Kissimmee, FL (US); Charles A. Storey, Orlando, FL (US)

Correspondence Address: HITT GAINES & BOISBRUN P.C., P.O. BOX 832570, RICHARDSON, TX, 75083, US

(21) Appl. No.: 09/777,470

(22) Filed: Feb. 6, 2001

(51) Int. Cl. H01L 21/00

(52) U.S. Cl. 438/56

(57) ABSTRACT

The present invention provides an improved conditioning wheel for conditioning polishing pads used to polish semiconductor wafers. The conditioning wheel includes a planar body and a homogeneous abrasive layer located on the planar body wherein the homogenous abrasive layer includes abrasive protrusions comprised of a same material as the homogenous abrasive layer.

### TECHNICAL FIELD OF THE INVENTION

The present invention is directed, in general, to reconditioning a semiconductor wafer polishing pad and, more specifically, to an improved conditioning wheel for conditioning a semiconductor wafer polishing pad having an abrasive layer with abrasive protrusions extending therefrom.

### BACKGROUND OF THE INVENTION

In the manufacture of the integrated circuits (ICs) derived from semiconductor wafers, chemical-mechanical planarization (CMP) is used to provide smooth topographies of the wafer substrates on which ICs are formed for subsequent lithography and material deposition.

Unfortunately, during the CMP process the polishing pad often collects particulate material from the slurry, as well as byproducts from the polishing process. Over time, this material begins to clog the pad, inhibiting the CMP process. When the pad becomes clogged, it becomes necessary to condition the pad in order to restore its original shape and properties. That is, the material must be removed before it completely clogs the pad and results in a surface that does not effectively polish the semiconductor wafer, or a surface that scratches or otherwise damages the wafer. In short, to properly polish a semiconductor wafer, the performance of the polishing pad should not be compromised.

In conventional processes, to condition the polishing pad, a conditioning wheel with a surface of diamond abrasives embedded in a nickel/stainless steel alloy setting is used. For example, referring initially to FIG. 1, illustrated is a polishing pad conditioning wheel 100 found in the prior art. The conditioning wheel 100 includes a planar body 110 and an upper surface 120, typically composed of metal or a metal alloy, for conditioning a semiconductor wafer polishing pad (not illustrated).

The upper surface 120 of the conditioning wheel 100 includes abrasive particles, one of which is designated 140, that are embedded in the upper surface 120. The abrasive particles 140 are typically diamond crystals. These diamond crystals are well suited for conditioning the polishing surface of a polishing pad, which must be done periodically to keep the polishing pad at optimum polishing efficiency.

As the conditioning wheel 100 is repeatedly used, however, its effectiveness at reconditioning the surface of a polishing pad decreases. Perhaps the most common reason for this decrease may be that the abrasive particles 140 become worn and rounded, losing their polishing effectiveness. However, a more pressing concern for this degradation may be that the abrasive particles 140 in the upper surface 120 may become lose and fall out of the upper surface 120 of the conditioning wheel 100, as illustrated by arrow 150. Of course, this reduces the effective surface area of the conditioning wheel 100 and slows the conditioning process. Moreover, this condition becomes even more pressing if many abrasive particles 140 are lost from a single area of the upper surface 120. In such a case, the conditioning wheel 100 may begin to condition a polishing pad unevenly, which may translate into damaging or unevenly polishing a semiconductor wafer undergoing the CMP process. Once dislodged, the abrasive particles 140 that fall from the conditioning wheel 100 cannot be replaced with new particles. In time, when a substantial number of abrasive particles 140 have been lost, the capabilities of the conditioning wheel 100 are so lost that it must be replaced with a new one, usually at significant costs.

Perhaps more importantly, the loss of abrasive particles 140 during the conditioning process is not only undesirable from a cost standpoint, but also from a quality standpoint as the abrasive particles 140 can become embedded in the polishing pad just conditioned. Once embedded in the polishing pad, the abrasive particles 140 can easily scratch a semiconductor wafer undergoing CMP, in some cases damaging it beyond repair. With the high cost of semiconductor materials, manufacturers are understandably eager to avoid damaging, and thus, discarding wafers during the CMP process.

Accordingly, what is needed in the art is an improved conditioning wheel for conditioning a semiconductor wafer polishing pad that does not suffer from the deficiencies found in the prior art.

### SUMMARY OF THE INVENTION

To address the above-discussed deficiencies of the prior art, the present invention provides an improved polishing pad conditioning wheel. In one embodiment, the conditioning wheel includes a planar body and a homogeneous abrasive layer located on the planar body, the homogenous abrasive layer including abrasive protrusions comprised of a same material as the homogenous abrasive layer. In this advantageous embodiment, since the abrasive protrusions and abrasive layer are comprised of the same material, conditioning of a semiconductor wafer polishing pad may be done in-situ, increasing the throughput of the conditioning wheel.

The foregoing has outlined, rather broadly, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

For a more complete understanding of the present invention, reference is now made to the following descriptions taken in conjunction with the accompanying drawings, in which:

FIG. 1 illustrates a polishing pad conditioning wheel found in the prior art;

FIG. 2 illustrates a polishing pad conditioning wheel manufactured according to the principles of the present invention;

FIG. 3A illustrates a sectional view of a conventional polishing apparatus polishing a semiconductor wafer; and

FIG. 3B illustrates a sectional view of the conventional polishing apparatus of FIG. 3A incorporating a conditioning wheel according to the present invention.

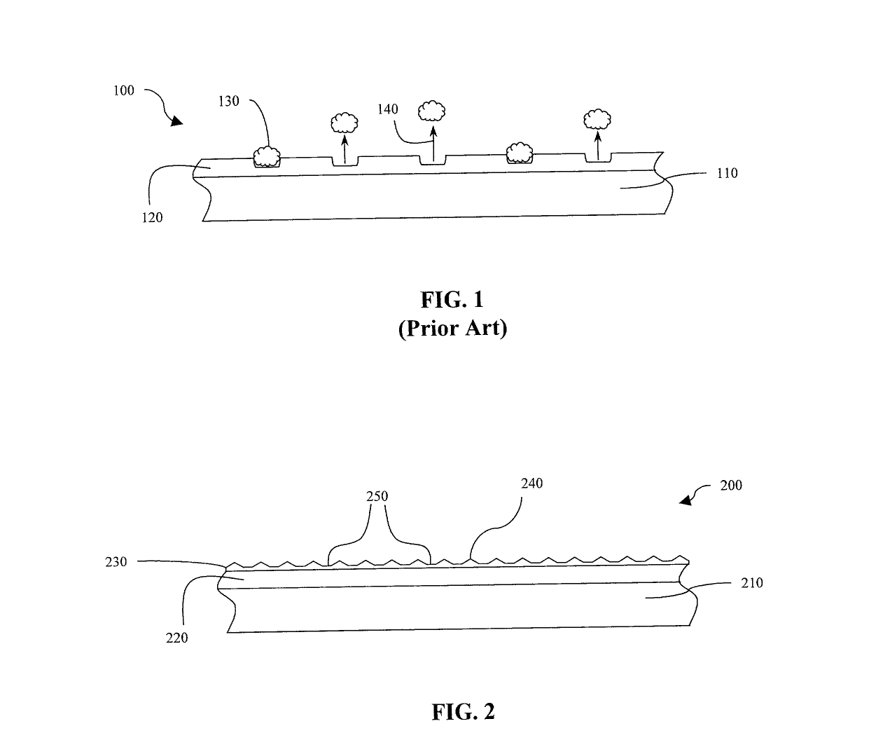

### DETAILED DESCRIPTION

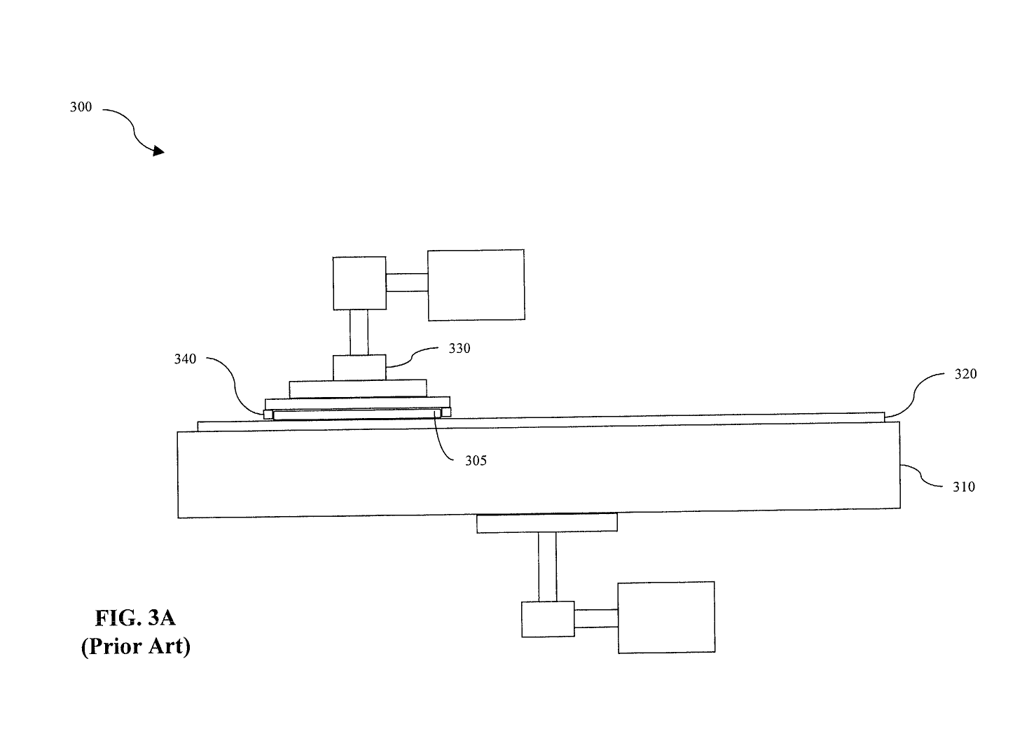

Referring now to FIG. 2, illustrated is a polishing pad conditioning wheel 200 manufactured according to the principles of the present invention. Like the conditioning wheel 100 of the prior art, the conditioning wheel 200 includes a planar body 210 and an upper surface 220. In an advantageous embodiment, the planar body 210 has an annular configuration, however the present invention is broad enough to encompasses other configurations. In such an embodiment, the conditioning wheel 200 conditions a polishing pad (not illustrated) by rotating against, and maneuvering across, the pad's polishing surface.

In the illustrated embodiment, the upper surface 220 is a metal surface, and in an advantageous embodiment may be comprised of a nickel-chrome alloy or stainless steel. However a conditioning wheel 200 according to the present invention is broad enough to encompass any material suitable for use in the upper surface 220 of the planar body 210. In fact, a conditioning wheel 200 of the present invention does not require that the upper surface be comprised of a metal surface at all, although advantageous embodiments may make use of the strength and durability of conventional metals and metal alloys.

Unlike conditioning wheels found in the prior art, the upper surface 220 of the conditioning wheel 200 of the present invention does not necessarily include abrasive particles embedded therein, but the abrasive layer as discussed below may cover the embedded particles, if so desired. As discussed above, many of the abrasive particles embedded in conventional conditioning wheels typically become dislodged from the wheel and lost before they become worn to the extent that they can no longer effectively condition a polishing pad. More importantly, once these abrasive particles become dislodged, they often become embedded in the polishing pad being conditioned, and can easily scratch or otherwise damage future semiconductor wafers polished with that polishing pad.

To remedy the problems associated with the above-discussed prior art devices, the present invention provides a homogeneous abrasive layer 230 located on the upper surface 220 of the planar body 210. The abrasive layer 230 is homogeneous in that it maintains a uniform composition throughout. Additionally, the abrasive layer 230 includes abrasive protrusions 240 extending from the upper layer 220. More specifically, the abrasive protrusions 240 are comprised of the same material as the abrasive layer 230. These abrasive protrusions 240 provide a degree of abrasiveness to the upper surface 220 of the conditioning wheel 200 for conditioning semiconductor wafer polishing pads.

In an advantageous embodiment, since the abrasive layer 230 having the abrasive protrusions 240 replaces any abrasive particles embedded in the upper surface 220, a conditioning wheel 200 according to the present invention will not experience abrasive particles falling from the upper surface 220 and thereby contaminating a polishing pad. By not embedding abrasive particles in the upper surface 220, a conditioning wheel according to the present invention can successfully condition numerous polishing pads, while virtually eliminating the risk of contamination caused by dislodged particles. Without this risk, manufacturers may polish semiconductor wafers with the confidence that those wafers will not be scratched or otherwise damaged by such dislodged particles.

In one aspect of the present invention, the abrasive protrusions 240 are formed when the abrasive layer 230 is deposited on the upper surface 220. In this advantageous embodiment, the abrasive protrusions 240 are simply formed from asperities in the outer surface of the abrasive layer 230 and provide a degree of abrasiveness to the abrasive layer 230. However, in an alternative embodiment, the abrasive protrusions 240 are etched by conventional techniques or otherwise defined from the abrasive layer 230 once the abrasive layer 230 has been deposited on the upper surface 220. Those having skill in the art are familiar with conventional etching techniques, and how those techniques vary depending on the composition of the abrasive layer 230.

In a particularly advantageous embodiment, the abrasive layer 23 is comprised of polycrystalline diamond such as formed by chemical vapor deposition (CVD). As used with regard to the present invention, polycrystalline diamond is defined as the deposition or growth of diamond crystals on a surface, perhaps through a CVD process, which results in a microcrystalline diamond film being formed on the surface. In this embodiment, to create a polycrystalline diamond abrasive layer 230, polycrystalline diamond is deposited onto the upper surface 220 of the conditioning wheel 200 through a CVD process. Those skilled in the art are familiar with such CVD processes, as well as the tendency of the CVD process to create an ultra-thin film having a certain degree of abrasiveness, as a result of varying asperities, depending on the CVD technique used to deposit the film.

In such an embodiment, polycrystalline diamond is used as the abrasive layer 230 because of the superior wear-resistance of the diamond crystals formed on the upper surface 220. Because of this superior wear-resistance, a polycrystalline diamond abrasive layer 230 could effectively condition substantially more polishing pads than conditioning wheels found in the prior art before the need to be replaced. Since the abrasive protrusions 240 are comprised of the same material as the abrasive layer 230, in a related embodiment, the abrasive protrusions 240 are also composed of polycrystalline diamond. In this embodiment, the abrasive protrusions 240 also have the benefits of diamond crystals, and assist in conditioning substantially more polishing pads than prior art conditioning wheels.

In yet another advantageous embodiment of the present invention, the abrasive layer 230 and abrasive protrusions 240 are comprised of silicon carbide. In this particular embodiment, the silicon carbide abrasive layer 230 also eliminates the need to embed abrasive particles in the conditioning wheel 200, however, it does not preclude the use of an embedded abrasive material, if so desired. In either event, the presence of the silicon carbide abrasive layer 230 inhibits any dislodged particles from contaminating the polishing pad being conditioned. Those skilled in the art are also familiar with the advantages associated with the use of silicon carbide, such as increased wear-resistance and increased heat resistance. In one aspect of this particular embodiment, the silicon carbide abrasive layer 230 may be a chemical vapor deposition silicon carbide (CVD silicon carbide) layer. As used with regard to the present invention, CVD silicon carbide is defined as the deposition or growth of silicon carbide on a surface, through a CVD process, which results in a silicon carbide film forming on the surface. Like the polycrystalline diamond discussed above, the CVD silicon carbide abrasive layer 230 also replaces any abrasive particles embedded in the upper surface 220, thus preventing the contamination caused by particles that become dislodged from the conditioning wheel 200.

In the illustrated embodiment, the abrasive protrusions 240 may also be arranged in a pattern. More specifically, in a particularly advantageous embodiment of the conditioning wheel 200, the abrasive protrusions 240 may be conventionally etched from the abrasive layer 230 in a selected pattern. This pattern is then repeated across the entire conditioning surface of the conditioning wheel 200 so as to provide a precise pattern of abrasive protrusions 240 on the abrasive layer 230. By selecting such a precise pattern, manufacturers have more freedom to choose a degree of abrasiveness, and can more easily repeat desirable conditioning results from one polishing pad to another. In such embodiments, when the abrasive protrusions 240 become overly worn, new protrusions 240 may easily be etched in the abrasive layer 230 without the need to redeposit an abrasive layer 230 on the upper surface 220. Moreover, the new abrasive protrusions 240 may be etched from the abrasive layer 230 in an identical pattern, or the pattern may be slightly modified based on the results of prior conditioning processes. Those skilled in the art understand the etching processes needed to etch the abrasive layer 230. Now having the ability to etch new abrasive protrusions 240 significantly extends the life of the conditioning wheel 200 beyond that of the prior art conditioning wheels.

In view of the disclosed embodiments, the conditioning wheel 200 provided by the present invention provides numerous advantages over wheels found in the prior art. Among the most significant advantages is preventing the contamination of polishing pads caused by abrasive particles becoming dislodged during the conditioning process. By eliminating the need for embedding abrasive particles in the conditioning wheel 200 or by depositing the abrasive layer 230 over the embedded particles, the conditioning wheel 200 provides the protection against scratching or otherwise damaging semiconductor wafers undergoing CMP unavailable in the prior art. Of course, the present invention also provides other important advantages including incorporating known various CVD processes that result in an abrasive layer 230 having asperities that provide the desired abrasiveness of the conditioning wheel 200. Alternatively, the abrasive protrusions 240 may be etched or be otherwise defined from the abrasive layer 230 to provide the desired abrasiveness.

In addition, the abrasive layer 230 and abrasive protrusions 240 further provide an increased wear-resistance over many of the conventional materials used in the prior art. Specifically, the hardness of the two, especially in embodiments using polycrystalline diamond, provides extra life for the conditioning wheel 200 due to the superior wear-resistance of the diamond crystals. Furthermore, where conditioning wheels in the prior art cannot be repaired and reused once the abrasive particles are lost or excessively worn, the conditioning wheel 200 of the present invention may easily have a new abrasive layer 230 deposited on the upper surface 220 when a prior layer has significantly worn and no longer efficiently conditions polishing pads.

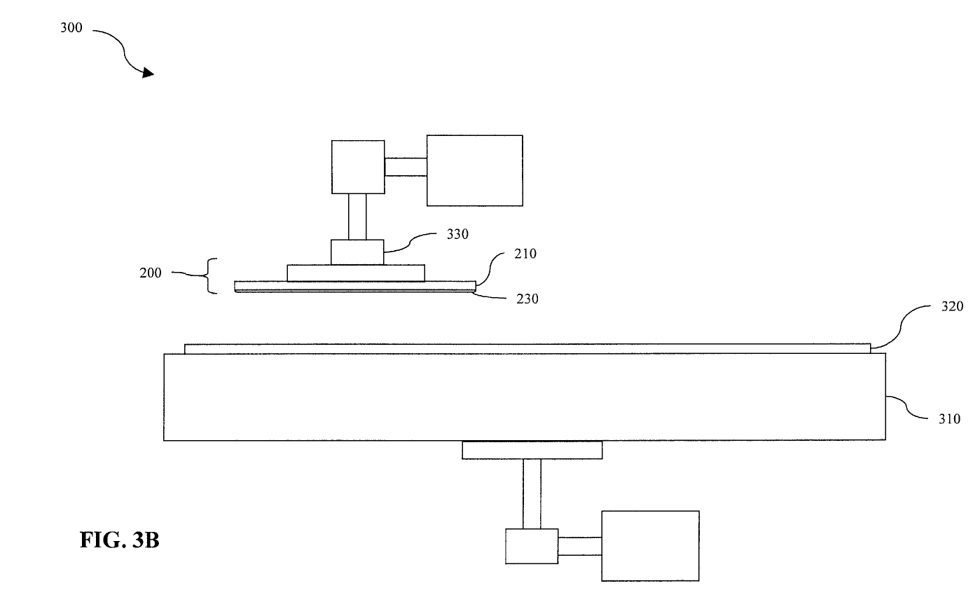

Turning now to FIGS. 3A and 3B, concurrently, illustrated is an example of a conventional polishing apparatus 300 that can be used to polish a semiconductor wafer 305, and that can be used in conjunction with the present invention. Those who are skilled in the art understand how to make and use the polishing apparatus 300 illustrated in FIGS. 3A and 3B, as well as how to condition a polishing pad. Basically, the polishing apparatus 300 includes a polishing platen 310 and a polishing pad 320 attached to the polishing platen 310 that is used to polish the semiconductor wafer 305, perhaps during a CMP process.

The polishing apparatus 300 further includes a carrier head 330. As illustrated in FIG. 3B, removably mounted to the carrier head 330 is the conditioning wheel 200 illustrated in FIG. 2. The conditioning wheel 200 is removable so that the carrier head 330 may accommodate a carrier ring 340 and the semiconductor wafer 305 for a polishing operation, as illustrated in FIG. 3A. When the polishing effectiveness of the polishing pad 320 is lost or has diminished, the conditioning wheel 200 is mounted to the carrier head 330 and used to condition the polishing pad 320 to restore its polishing effectiveness. In other embodiments of the present invention, the conditioning wheel 200 is a complete assembly, incorporating the carrier head 430 as part of a single assembly. In addition, other assemblies incorporating the conditioning wheel 200 are also encompassed by the present invention.

After the polishing pad 320 has been used to polish numerous semiconductor wafers 305, its polishing surface eventually degrades to the point of requiring conditioning to return its polishing efficiency. In such instances, the carrier ring 340 and the semiconductor wafer 305 are removed from the carrier head 330, and the conditioning wheel 200 of the present invention is attached to the carrier head 330 and used to condition the polishing pad 320. When conditioning of the polishing pad 320 is completed, the conditioning wheel 200 is removed from the carrier head 330, and the carrier ring 340 is reattached to the carrier head 330 so that future semiconductor wafers 305 may be polished. This conditioning procedure is, of course, repeated whenever necessary to restore the effectiveness of the polishing pad.

Thus, with the durability of the abrasive layer 230 of the present invention, especially in embodiments incorporating a polycrystalline diamond, the conditioning wheel 200 of the present invention may be used to condition significantly more polishing pads 320 than conditioning wheels found in the prior art and done so without the risk of contaminating those polishing pads 320 with dislodged abrasive particles, thereby damaging semiconductor wafers 305.

Although the present invention has been described in detail, referring to several embodiments, those skilled in the art should understand that they can make various changes, substitutions and alterations herein without departing from the spirit and scope of the invention in its broadest form.

What is claimed is:

1. A polishing pad conditioning wheel, comprising:
a planar body; and
an abrasive layer located on the planar body, the abrasive layer including abrasive protrusions comprised of a same material as the abrasive layer.

2. The polishing pad conditioning wheel as recited in claim 1 wherein the abrasive layer comprises polycrystalline diamond.

3. The polishing pad conditioning wheel as recited in claim 2 wherein the abrasive layer is a homogenous abrasive layer.

4. The polishing pad conditioning wheel as recited in claim 1 wherein the abrasive layer comprises silicon carbide.

5. The polishing pad conditioning wheel as recited in claim 4 wherein the silicon carbide is deposited by chemical vapor deposition.

6. The polishing pad conditioning wheel as recited in claim 1 wherein the abrasive protrusions are arranged in a repeated pattern.

7. The polishing pad conditioning wheel as recited in claim 1 wherein the planar body includes a metal surface and the homogeneous abrasive layer is located on the metal surface.

8. The polishing pad conditioning wheel as recited in claim 7 wherein the metal surface is stainless steel.

9. The polishing pad conditioning wheel as recited in claim 7 wherein the metal surface is a nickel-chrome alloy.

10. The polishing pad conditioning wheel as recited in claim 1 wherein the planar body is free of an abrasive embedded layer.

11. A polishing apparatus, comprising:
a carrier head coupled to a motor;
a polishing platen;
a polishing pad located on the polishing platen; and a polishing pad conditioning wheel, including:
a planar body; and
an abrasive layer located on the planar body, the abrasive layer including abrasive protrusions comprised of a same material as the abrasive layer.

12. The polishing pad conditioning wheel as recited in claim 11 wherein the abrasive layer comprises polycrystalline diamond.

13. The polishing pad conditioning wheel as recited in claim 12 wherein the abrasive layer is a homogenous abrasive layer.

14. The polishing pad conditioning wheel as recited in claim 11 wherein the homogeneous abrasive layer comprises silicon carbide.

15. The polishing pad conditioning wheel as recited in claim 14 wherein the silicon carbide is deposited by chemical vapor deposition.

16. The polishing pad conditioning wheel as recited in claim 11 wherein the abrasive protrusions are arranged in a repeated pattern.

17. The polishing pad conditioning wheel as recited in claim 11 wherein the planar body includes a metal surface and the homogeneous abrasive layer is located on the metal surface.

18. A method of conditioning a polishing pad, comprising:
providing a conditioning wheel with an abrasive layer located on a planar body, the abrasive layer including abrasive protrusions comprised of a same material as the abrasive layer;
coupling the conditioning wheel to a carrier head of a polishing apparatus;
placing the conditioning wheel against a polishing pad; and
conditioning the polishing pad with the abrasive protrusions.

19. The method as recited in claim 18 wherein conditioning is effected by movement of polycrystalline diamond across the polishing pad.

20. The method as recited in claim 18 wherein conditioning is effected by movement of silicon carbide across the polishing pad.

21. The method as recited in claim 18 further including polishing a semiconductor wafer with the polishing pad prior to the conditioning and polishing the semiconductor wafer with the polishing pad subsequent to the conditioning.
